(19) United States
(12) Patent Application Publication
(10) Pub. No.: US 2014/0217391 A1
(43) Pub. Date: Aug. 7, 2014

(54) ORGANIC EL ELEMENT AND METHOD FOR MANUFACTURING SAME

(71) Applicant: Panasonic Corporation, Kadoma-shi, Osaka (JP)

(72) Inventors: Yoshiki Hayasaki, Osaka (JP); Toru Baba, Hyogo (JP); Takeo Sirai, Osaka (JP)

(21) Appl. No.: 14/342,695

(22) PCT Filed: Oct. 1, 2012
(86) PCT No.: PCT/JP2012/006268

§ 371 Date: Mar. 4, 2014

(30) Foreign Application Priority Data
Oct. 4, 2011 (JP) 2011-220532

(51) Int. Cl. H01L 51/52; H01L 51/00

(52) U.S. Cl. CPC H01L 51/5209; H01L 51/0023; H01L 51/5225
USPC 257/40; 438/26

(57) ABSTRACT

An organic EL element includes an organic EL substrate 4 including an organic light emitting unit provided on a translucent substrate, and a sealing cap substrate sealing the light emitting unit. The organic EL substrate includes first electrode taking-out pads and provided in electrodes which feed power to the light emitting unit, and a first bonding portion 40 provided in a peripheral portion of the translucent substrate. The sealing cap substrate includes second electrode taking-out pads and facing the first electrode taking-out pads, through-wiring and passing through the sealing cap substrate, and a second bonding portion facing the first bonding portion. The first bonding portion and the second bonding portion are bonded together through surface activated bonding.

### TECHNICAL FIELD

The present invention relates to an organic EL element in which an organic light emitting unit is sealed, and to a method for manufacturing the same.

### BACKGROUND ART

Organic EL elements are capable of emitting light of high luminance with a low voltage, and various colors of emitted light are obtained depending on the types of organic materials used in an organic light emitting layer. In addition, organic EL elements are easy to be manufactured as planar light emitting panels. Thus, in recent years, attentions have been paid to lighting apparatuses including a light emitting panel using an organic EL element as a light source.

In general, an organic material used in an organic light emitting unit deteriorates under influence of moisture, oxygen, and the like, which leads to reduced light emitting performance and life thereof. Therefore, in the organic EL element, in order to protect the organic material from moisture, oxygen, and the like, a sealing structure for sealing the organic light emitting unit is employed. An organic EL element including such a sealing structure is shown in FIG. 5. As shown in FIGS. 5(a) and 5(b), an organic EL element 101 includes: an organic EL substrate 104 having an organic light emitting unit 103 formed on one surface of a translucent substrate 102; and a sealing cap substrate 105 which is provided on the organic EL substrate 104 and which seals the organic light emitting unit 103. On the translucent substrate 102, a lower electrode 131 formed from a translucent electrically-conductive material such as ITO or the like is patterned. The organic light emitting unit 103 is formed so as to extend over the lower electrode 131 and a part of the translucent substrate 102. On the organic light emitting unit 103 and on a portion, of the lower electrode 131, for which the organic light emitting unit 103 is not provided, an upper electrode 132 having a light reflecting property is formed. In the sealing cap substrate 105, at a position corresponding to the organic light emitting unit 103, a recess 151 is formed. In a peripheral portion of this recess 151, the sealing cap substrate 105 is bonded to the organic EL substrate 104 via an adhesive resin material 140.

However, in this configuration, in order to feed power to the organic light emitting unit 103, it is necessary to extend parts of the lower electrode 131 to the outside of the element to provide electrode taking-out portions (positive electrode 131a and negative electrode 131b). Further, the positive electrode 131a and the negative electrode 131b are formed with a predetermined interval therebetween so as to be insulated from each other. Therefore, on the organic EL substrate 104, there are steps between a portion on which the positive electrode 131a and the negative electrode 131b are formed and a portion on which neither the positive electrode 131a nor the negative electrode 131b are formed. As shown in FIG. 5(c), if the resin material 140 is provided with a constant film thickness so as to extend over these steps, a gap G occurs between the resin material 140 and the sealing cap substrate 105 as shown in FIG. 5(d), and thus, the resin material 140 and the sealing cap substrate 105 cannot be bonded together in a state where a hermetic state is maintained.

Thus, there has been known an organic EL device in which an organic light emitting unit is sealed with a flexible cap substrate and through-wiring passing through the cap substrate is provided, thereby eliminating steps at a bonding surface between a translucent substrate and the cap substrate (see Patent Document 1, for example).

### PRIOR ART DOCUMENT

### Patent Document

Patent Document 1: Japanese Laid-Open Patent Publication No. 2000-243555

### DISCLOSURE OF THE INVENTION

### Problems to be Solved

However, in the organic EL device of Patent Document 1 above, since the translucent substrate and the cap substrate for sealing are bonded together with a resin, and thus, air-tightness is poor. Accordingly, there is a risk of moisture or oxygen entering from an interface between the resin and each substrate, causing deterioration of the organic material from a peripheral portion of the organic light emitting unit. Further, depending on the type of the resin, curing processing using heat is required when the substrates are to be bonded together, and there is also a risk of deterioration of the organic material caused by this heat.

The present invention has been made to solve the above problems. An object of the present invention is to provide an organic EL element which is capable of sealing an organic light emitting unit in a hermetic state and which is less likely to allow deterioration of the organic light emitting unit, and to provide a method for manufacturing the same.

### Means to Solve the Problems

In order to solve the above problem, an organic EL element according to the present invention is an organic EL element including: an organic EL substrate including an organic light emitting unit provided on one surface of a translucent substrate; and a sealing cap substrate which is provided on the organic EL substrate and which seals the organic light emitting unit, the organic EL substrate including: a lower electrode and an upper electrode which feed power to the organic light emitting unit; a first electrode taking-out pad provided in these electrodes; and a first bonding portion provided in a peripheral portion of the translucent substrate, the sealing cap substrate including: a recess provided at a position opposed to the organic light emitting unit; a second electrode taking-out pad provided at a position opposed to the first electrode taking-out pad; through-wiring provided so as to pass through the sealing cap substrate from the second electrode taking-out pad to an opposite side of the organic EL substrate; and a second bonding portion provided at a position opposed to the first bonding portion, and the first bonding portion and the second bonding portion being bonded together through surface activated bonding.

In the above organic EL element, preferably, a connection surface between the first electrode taking-out pad and the second electrode taking-out pad is flush with a bonding interface between the first bonding portion and the second bonding portion.

In the above organic EL element, preferably, as the first bonding portion, either one or both of the lower electrode and the upper electrode is(are) used.

In the above organic EL element, preferably, the first bonding portion is formed integrally with the first electrode taking-out pad, and the second bonding portion is formed integrally with the second electrode taking-out pad.

The above organic EL element is preferably manufactured by a method for manufacturing an organic EL element, the method including: a step of forming, on a translucent substrate, lower electrodes respectively corresponding to a positive electrode and a negative electrode which feed power to an organic light emitting unit; a step of forming the organic light emitting unit so as to extend over the translucent substrate and a lower electrode; a step of forming upper electrodes on the lower electrodes and on the organic light emitting unit, and of determining portions, of the upper electrodes, for which the organic light emitting unit is not provided, as first electrode taking-out pads; a step of forming, in a peripheral portion of the translucent substrate, a first bonding portion so as to be flush with the upper electrodes; a step of forming a recess at a position, in a sealing cap substrate sealing the organic light emitting unit, opposed to the organic light emitting unit; a step of forming through-holes at positions, in the sealing cap substrate, opposed to the first electrode taking-out pads; a step of forming through-wiring in the through-holes; a step of forming a second bonding portion and second electrode taking-out pads at positions, in the sealing cap substrate, opposed to the first bonding portion and the first electrode taking-out pads, respectively; and a step of bonding the first bonding portion and the second bonding portion together through surface activated bonding, in a state where the first electrode taking-out pads are respectively in contact with the second electrode taking-out pads.

### Advantageous Effects of the Invention

According to the present invention, the first bonding portion provided in the peripheral portion of the translucent substrate in the organic EL substrate and the second bonding portion of the sealing cap substrate are bonded together through surface activated bonding. Thus, the organic light emitting unit can be sealed in a hermetic state, and the organic light emitting unit is less likely to be deteriorated.

### BRIEF DESCRIPTION OF THE DRAWINGS

FIG. 1(a) is a side cross-sectional view of an organic EL element according to one embodiment of the present invention, FIG. 1(b) is a top view of an organic EL substrate of the organic EL element, FIG. 1(c) is a bottom view of a sealing cap substrate of the organic EL element, and FIG. 1(d) is a top view of the sealing cap substrate of the organic EL element.

Each of FIGS. 2(a) to 2(k) is a side cross-sectional view for describing a method for manufacturing the organic EL element.

FIG. 3(a) is a side cross-sectional view of an organic EL element according to a modification of the above embodiment, FIG. 3(b) is a top view of an organic EL substrate of the organic EL element, FIG. 3(c) is a bottom view of a sealing cap substrate of the organic EL element, and FIG. 3(d) is a top view of the sealing cap substrate of the organic EL element.

FIG. 4(a) is a side cross-sectional view of an organic EL element according to another modification of the above embodiment, FIG. 4(b) is a top view of an organic EL substrate of the organic EL element, FIG. 4(c) is a bottom view of a sealing cap substrate of the organic EL element, and FIG. 4(d) is a top view of the sealing cap substrate of the organic EL element.

FIG. 5(a) is a top view of a conventional organic EL element, FIG. 5(b) is a side cross-sectional view of the organic EL element including a cross section taken along an A-A line of FIG. 5(a), FIG. 5(c) is a cross-sectional view of FIG. 5(a) taken along a B-B line, and FIG. 5(d) is a side cross-sectional view of the organic EL element including the B-B line cross section of FIG. 5(a).

### DESCRIPTION OF THE PREFERRED EMBODIMENTS

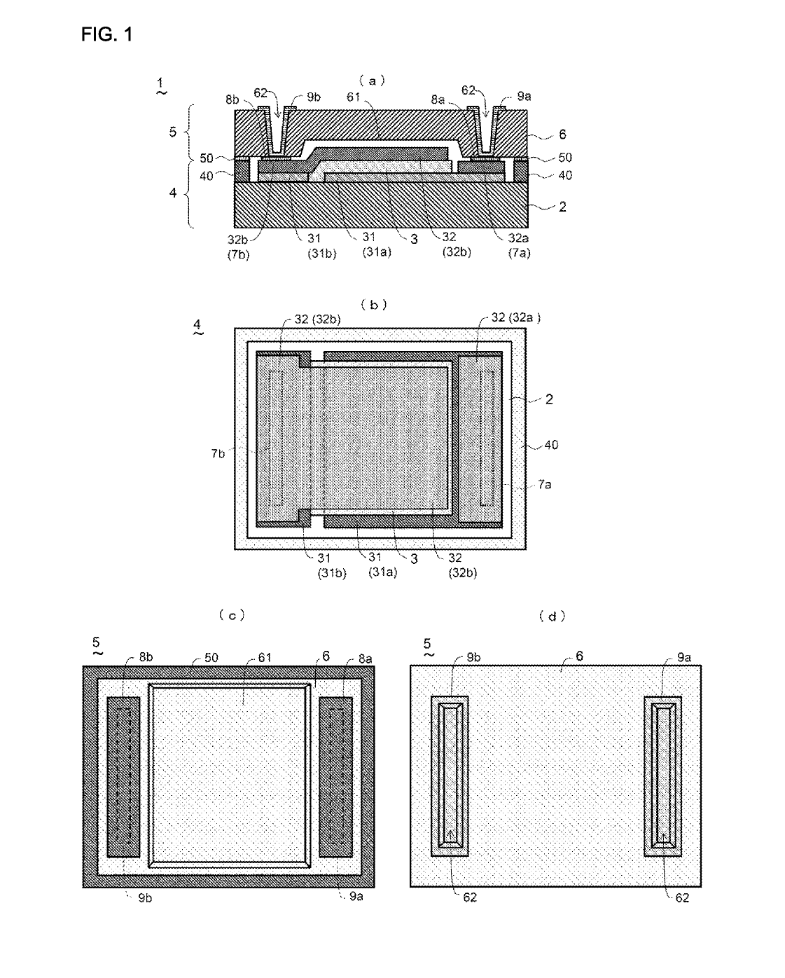

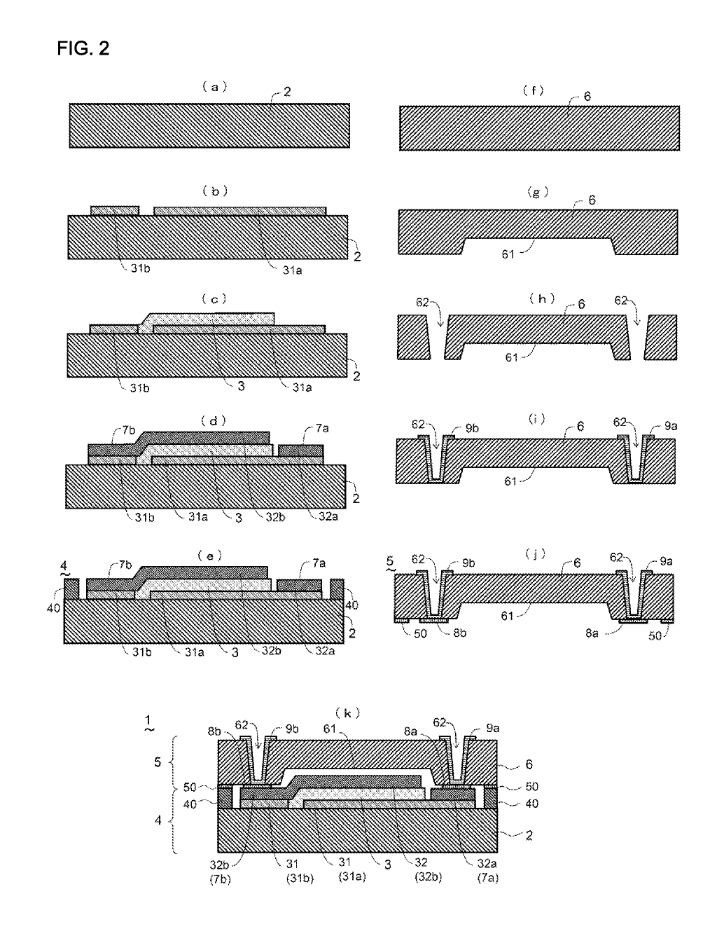

A configuration of an organic EL element according to one embodiment of the present invention will be described with reference to FIG. 1 and FIG. 2. As shown in FIG. 1(a), an organic EL element 1 of the present embodiment includes: an organic EL substrate 4 including an organic light emitting unit 3 formed on one surface of a translucent substrate 2; and a sealing cap substrate 5 which is provided on the organic EL substrate 4 and which seals the organic light emitting unit 3.

The translucent substrate 2 is a rectangular planar plate member having translucency, and for example, a rigid glass plate such as soda glass, alkali-free glass, or the like, a flexible plastic plate such as polycarbonate, polyethylene terephthalate, or the like is used. On the translucent substrate 2, a lower electrode 31 is patterned, and the organic light emitting unit 3 is formed so as to extend over a part of the translucent substrate 2 and the lower electrode 31. On the organic light emitting unit 3 and on portions, of the lower electrode 31, on which the organic light emitting unit 3 is not formed, an upper electrode 32 is formed.

The lower electrode 31 is composed of a positive electrode 31a and a negative electrode 31b respectively connected to a hole injection side and an electron injection side of the organic light emitting unit 3. As shown in FIG. 1(b), the positive electrode 31a is formed in a relatively large region including a central portion of the translucent substrate 2. The negative electrode 31b is formed, on the translucent substrate 2, with a predetermined interval from the positive electrode 31a so as to be insulated from the positive electrode 31a. Further, the positive electrode 31a and the negative electrode 31b are formed with a certain interval from a peripheral edge of the translucent substrate 2. The lower electrode 31 composed of the positive electrode 31a and the negative electrode 31b is formed from an electrically-conductive material having translucency, such as ITO, IZO, tin oxide, zinc oxide, or the like.

The organic light emitting unit 3 is formed so as to extend over the positive electrode 31a and over a portion of the translucent substrate 2 positioned between the positive electrode 31a and the negative electrode 31b. At this time, the organic light emitting unit 3 is not formed on an end portion, of the positive electrode 31a, that is opposite to an end portion thereof close to the negative electrode 31b. The organic light emitting unit 3 is formed as a multilayer film in which, for example, from the positive electrode 31a side, a hole injection layer, a hole transport layer, a light emitting layer including an organic light emitting material, an electron transport layer, and an electron injection layer are laminated in this order. As materials forming these layers, organic materials generally used in the technical field of organic EL elements are used as appropriate.

The upper electrode 32 is also composed of a positive electrode 32a and a negative electrode 32b respectively connected to the hole injection side and the electron injection side of the organic light emitting unit 3. The positive electrode 32a is formed on a portion, of the positive electrode 31a of the lower electrode 31, on which the organic light emitting unit 3 is not formed, so as not to be in contact with the organic light emitting unit 3. The negative electrode 32b is formed on the organic light emitting unit 3 and on the negative electrode 31b of the lower electrode 31, so as to extend over these. The upper electrode 32 composed of the positive electrode 32a and the negative electrode 32b is formed from an electrically-conductive metal material having light reflecting property, such as aluminum, silver, magnesium, or the like.

Since the lower electrode 31, the organic light emitting unit 3, and the upper electrode 32 are respectively formed into the shapes as described above, a central region of the organic EL substrate 4 has a structure in which the lower electrode 31, the organic light emitting unit 3, and the upper electrode 32 are laminated. In addition, in regions for which the organic light emitting unit 3 is not formed, that is, on both sides of the central region mentioned above, the positive electrodes 31a and 32a are laminated, and the negative electrodes 31b and 32b are laminated, respectively. The positive electrode 32a and the negative electrode 32b themselves, which face the sealing cap substrate 5, respectively serve as first electrode taking-out pads 7a and 7b of the organic EL substrate 4 (see also FIG. 1(b)). Since the first electrode taking-out pads 7a and 7b each have a structure in which the upper electrode 32 is laminated on the lower electrode 31, if, for example, these are formed by a vacuum evaporation method or the like, the heights of the first electrode taking-out pads 7a and 7b from the upper surface of the translucent substrate 2 become equal to each other and the upper surfaces of the first electrode taking-out pads 7a and 7b become flush with each other (see also FIG. 1(a)).

In a peripheral portion of the translucent substrate 4 (SIC. correctly 2), a first bonding portion 40 is formed, with a predetermined interval from the lower electrode 31, so as to surround the organic light emitting unit 3. The first bonding portion 40 is formed so as to have the same thickness as a thickness obtained by the lower electrode 31 and the upper electrode 32 being laminated together. Accordingly, the upper surfaces of the first electrode taking-out pads 7a and 7b and the first bonding portion 40 are flush with one another. The first bonding portion 40 is formed from a metal material such as gold, platinum, aluminum, silver, copper, magnesium, or the like.

As shown in FIGS. 1(c) and (d), the sealing cap substrate 5 includes: a sealing substrate 6 having a substantially same shape as that of the translucent substrate 2; and second electrode taking-out pads 8a and 8b provided at positions opposed to the first electrode taking-out pads 7a and 7b, respectively. The sealing substrate 6 includes a recess 61 formed at a position opposed to the organic light emitting unit 3. The recess 61 prevents the upper electrode 32 (the negative electrode 32b) protruding due to the thickness of the organic light emitting unit 3, from coming into contact with the sealing substrate 6 in a state where the organic EL substrate 4 and the sealing cap substrate 5 are bonded together. Further, the sealing substrate 6 includes through-holes 62 respectively formed so as to pass through the sealing substrate 6 from the second electrode taking-out pads 8a and 8b to an opposite side of the organic EL substrate 4. The sealing cap substrate 5 includes through-wiring 9a and 9b provided in the through-holes 62 and electrically connected to the second electrode taking-out pads 8a and 8b, respectively, and a second bonding portion 50 provided at a position opposed to the first bonding portion 40. As in the case of the first electrode taking-out pads 7a and 7b (the upper electrode 32), the second electrode taking-out pads 8a and 8b are each formed from an electrically-conductive metal material such as aluminum, silver, magnesium or the like. In addition, as in the case of the first bonding portion 40, the through-wiring 9a and 9b and the second bonding portion 50 are each formed from a metal material such as gold, platinum, aluminum, silver, copper, magnesium, or the like.

The second electrode taking-out pads 8a and 8b and the second bonding portion 50 are simultaneously formed by patterning, using the same material. Accordingly, the upper surfaces of the second electrode taking-out pads 8a and 8b and the second bonding portion 50 become flush with one another. Moreover, compared with a case where the second electrode taking-out pads 8a and 8b and the second bonding portion 50 are individually formed, manufacturing efficiency can be improved.

By the first bonding portion 40 and the second bonding portion 40(SIC. correctly 50) being bonded together through surface activated bonding, the sealing cap substrate 5 is fixed on the organic EL substrate 4, and the organic light emitting unit 3 is sealed with the sealing substrate 6. The surface activated bonding is a bonding method in which, in a vacuum chamber, bonding surfaces are subjected to sputter etching by use of ion beam, plasma (inert gas such as argon gas), or the like, to bring the bonding surfaces into an activated state where bonding strength thereof with other atoms is increased, whereby bonds of atoms are directly joined to each other. According to this surface activated bonding, strong bonding can be obtained even at room temperature, for example.

In the organic EL element 1, wiring for feeding power to the organic light emitting unit 3 is provided via the second electrode taking-out pads 8a and 8b and the through-wiring 9a and 9b provided in the sealing cap substrate 5. Thus, no taking-out electrodes and wirings exist on the bonding interface between the first bonding portion 40 and the second bonding portion 40(SIC. correctly 50), and thus, hermetic bonding between the organic EL substrate 4 and the sealing cap substrate 5 can be realized through surface activated bonding. Accordingly, compared with a case where the sealing cap substrate is bonded to the organic EL substrate with resin, the organic light emitting unit 3 can be more assuredly sealed, and thus, deterioration of the organic material used in the organic light emitting unit 3 can be suppressed. Further, since the bonding of the organic EL substrate 4 and the sealing cap substrate 5 together can be performed even at room temperature, the organic light emitting unit 3 is not exposed to heat during the bonding. Thus, denaturation and the like of the organic material in manufacturing steps can be suppressed, and the organic light emitting unit 3 becomes less likely to be deteriorated.

In the organic EL element 1, the upper surfaces of the first electrode taking-out pads 7a and 7b and the first bonding portion 40 are flush with one another, and the upper surfaces of the second electrode taking-out pads 8a and 8b and the second bonding portion 50 are flush with one another. Accordingly, the connection surface between the first electrode taking-out pad 7a and the second electrode taking-out pad 8a, and the connection surface between the first electrode taking-out pad 7b and the second electrode taking-out pad 8b are flush with the bonding interface between the first bonding portion 40 and the second bonding portion 50. Therefore, when the first bonding portion 40 and the second bonding portion 40(SIC. correctly 50) are bonded together, the connection surface between the first electrode taking-out pad 7a and the second electrode taking-out pad 8a, and the connection surface between the first electrode taking-out pad 7b and the second electrode taking-out pad 8b are electrically connected at the same time of the bonding. Further, the first electrode taking-out pad 7a of the organic EL substrate 4 can be bonded to the second electrode taking-out pad 8a of the sealing cap substrate 5, and the first electrode taking-out pad 7b of the organic EL substrate 4 can be bonded to the second electrode taking-out pad 8b of the sealing cap substrate 5, through surface activated bonding, as in the case of the first bonding portion 40 and the second bonding portion 50. Accordingly, connection between the first electrode taking-out pad 7a and the second electrode taking-out pad 8a and connection between the first electrode taking-out pad 7b and the second electrode taking-out pad 8b become strong, and also, bonding between the organic EL substrate 4 and the sealing cap substrate 5 can further be made strong.

Next, a method for manufacturing the organic EL element 1 will be described with reference to FIG. 2. First, on the translucent substrate 2 which is planar as shown in FIG. 2(a), the lower electrode 31 corresponding to the positive electrode 31a and the negative electrode 31b and for feeding power to the organic light emitting unit 3 is formed as shown in FIG. 2(b). The lower electrode 31 is formed: by forming an electrically-conductive layer on the translucent substrate 2 by use of a technique such as a vacuum evaporation method, a sputtering method, application, or the like, and then by performing patterning through a lift-off process or etching process using photolithography technology. Next, as shown in FIG. 2(c), the organic light emitting unit 3 is formed so as to extend over the translucent substrate 2 and the lower electrode 31. The organic light emitting unit 3 is formed: by forming the hole transport layer, the light emitting layer, and the like described above into a predetermined shape by use of a predetermined metal mask, by a technique such as a vacuum evaporation method, application, or the like. Subsequently, as shown in FIG. 2(d), on the lower electrode 31 and on the organic light emitting unit 3, the upper electrode 32 (the positive electrode 32a and the negative electrode 32b) is formed. Then, portions, of the upper electrode 32, for which the organic light emitting unit 3 is not provided, are determined as the first electrode taking-out pads 7a and 7b. The upper electrode 32 is formed by use of a technique such as a vacuum evaporation method, a sputtering method, or the like. Then, as shown in FIG. 2(e), in a peripheral portion of the translucent substrate 2, the first bonding portion 40 is formed so as to be flush with the upper electrode 32. The first bonding portion 40 is formed through patterning using a metal mask, photolithography, or the like, based on a technique such as a vacuum evaporation method, a sputtering method, or the like. The organic EL substrate 4 is manufactured through these steps.

Next, with respect to the sealing cap substrate 5, first, by use of the sealing substrate 6 having a substantially same shape as that of the translucent substrate 2 as shown in FIG. 2(f), the recess 61 is formed at a position opposed to the organic light emitting unit 3 as shown in FIG. 2(g). Next, as shown in FIG. 2(h), the through-holes 62 are formed at positions, in the sealing substrate 6, opposed to the first electrode taking-out pads 7a and 7b, respectively. The recess 61 and the through-holes 62 are worked by use of a technique such as photo blast, for example. Subsequently, as shown in FIG. 2(i), the through-wiring 9a and 9b are formed in the through-holes 62, respectively. The through-wiring 9a and 9b are each formed: by forming a film by use of a technique such as a vacuum evaporation method, a sputtering method, or the like, and then by performing filling by plating. Then, as shown in FIG. 2(j), the second bonding portion 50 and the second electrode taking-out pads 8a and 8b are formed at positions, in the sealing substrate 6, opposed to the first bonding portion 40 and the first electrode taking-out pads 7a and 7b, respectively. The second bonding portion 50 and the second electrode taking-out pads 8a and 8b are formed through patterning using a metal mask, photolithography, or the like, based on a technique such as a vacuum evaporation method, a sputtering method, or the like. The sealing cap substrate 5 is manufactured through these steps.

Then, as shown in FIG. 2(k), the organic EL substrate 4 and the sealing cap substrate 5 are bonded together, by bonding the first bonding portion 40 and the second bonding portion 50 together through surface activated bonding in a state where the first electrode taking-out pads 7a and 7b are in contact with the second electrode taking-out pads 8a and 8b, respectively. The organic EL element 1 is manufactured through these steps.

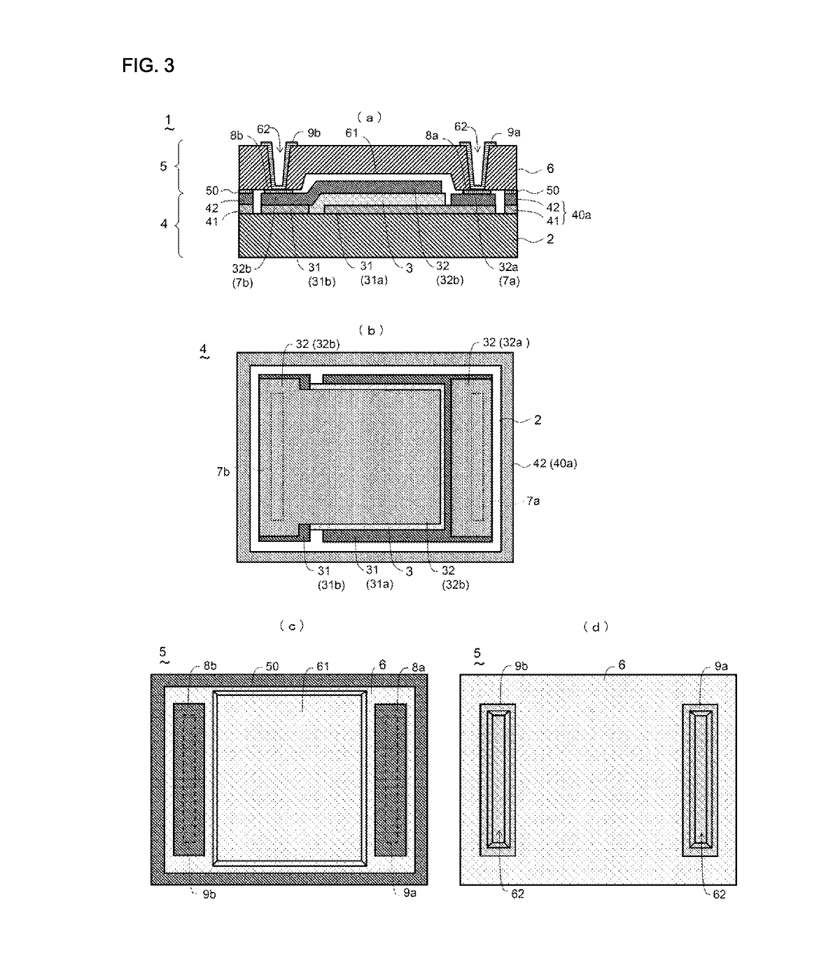

Next, an organic EL element according to a modification of the present embodiment will be described with reference to FIGS. 3(a) to 3(d). In the organic EL element 1 according to this modification, as a first bonding portion 40a, either one or both of the lower electrode 31 and the upper electrode 32 for feeding power to the organic light emitting unit 3 is(are) used. In this modification, specifically, the first bonding portion 40a is formed from a lower member 41 having the same configuration as that of the lower electrode 31 (the positive electrode 31a and the negative electrode 31b) and an upper member 42 having the same configuration as that of the upper electrode 32 (the positive electrode 32a and the negative electrode 32b). The lower member 41 and the upper member 42 are formed simultaneously with the lower electrode 31 and the upper electrode 32. The other configurations are the same as those in the above embodiment.

This modification eliminates the necessity of the step of separately forming the first bonding portion 40a, and thus, can improve manufacturing efficiency. Further, for example, in the embodiment described above, when the height of the first bonding portion 40 from the translucent substrate 2 is too great, the first electrode taking-out pads 7a and 7b do not come into contact with the second electrode taking-out pads 8a and 8b, respectively, at the time of bonding the first bonding portion 40 and the second bonding portion 50 together. On the other hand, when the height of the first bonding portion 40 is too small, the first bonding portion 40 cannot be bonded to the second bonding portion 50. In contrast, according to the present modification, the height of the upper surface, of the upper member 42, being the bonding interface with the second bonding portion 50 of the sealing cap substrate 5 can be made precisely the same as the heights of the first electrode taking-out pads 7a and 7b. Therefore, hermetic bonding between the organic EL substrate 4 and the sealing cap substrate 5 can be more assuredly performed through surface activated bonding.

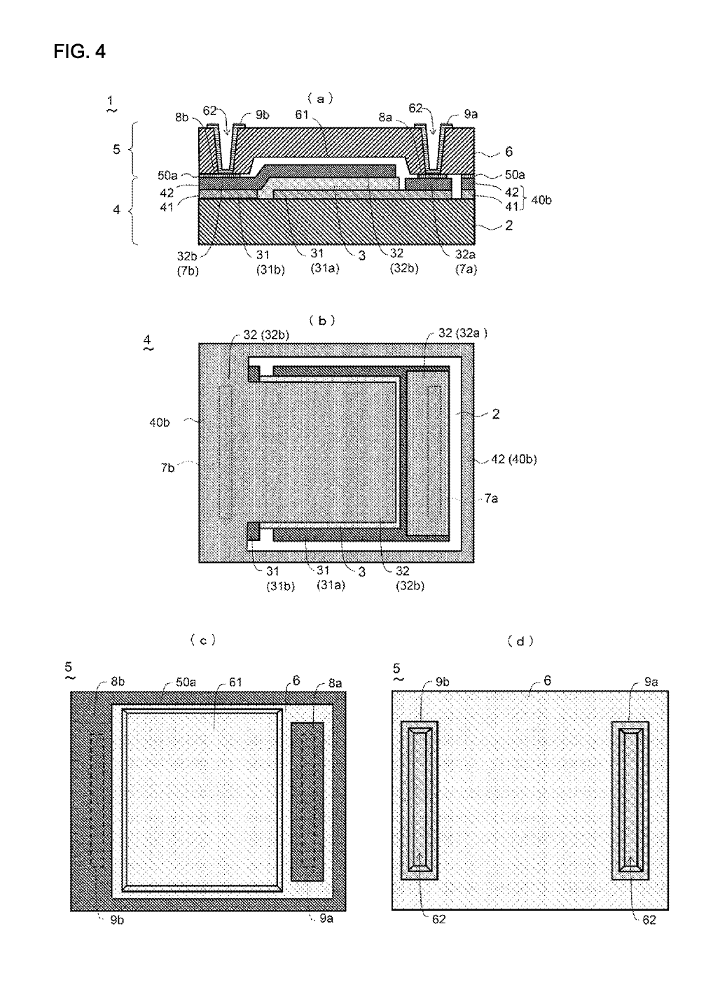

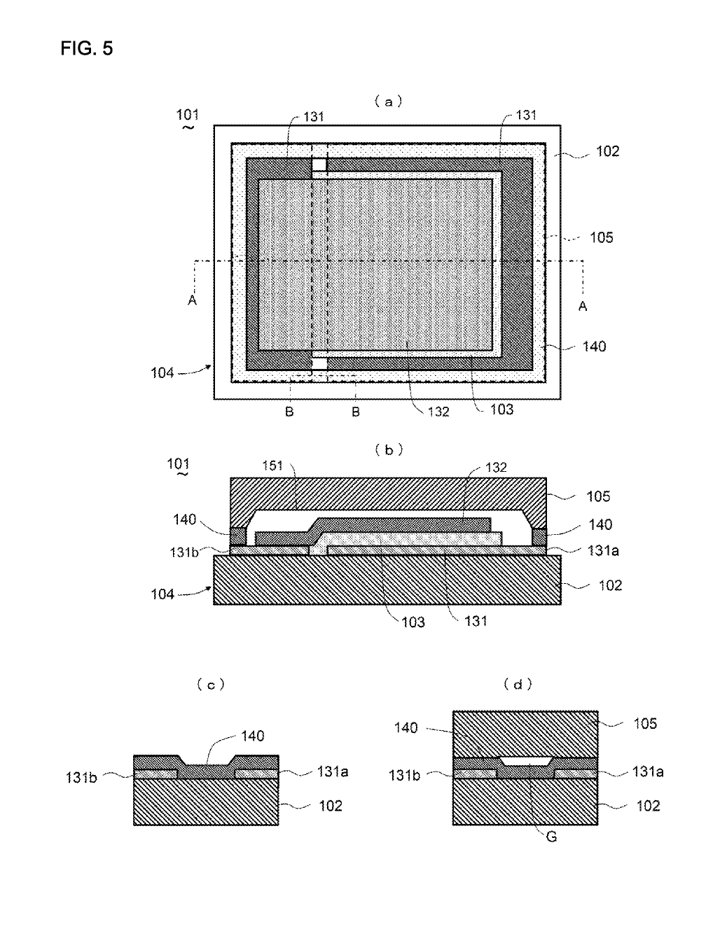

Next, an organic EL element according to another modification of the present embodiment will be described with reference to FIGS. 4(a) to 4(d). In the organic EL element 1 according to this modification, a first bonding portion 40b is formed integrally with the first electrode taking-out pad 7a or 7b. In addition, a second bonding portion 50a is formed integrally with the second electrode taking-out pad 8a or 8b. In this modification, specifically, as shown in FIGS. 4(a) and 4(b), the first bonding portion 40b is formed integrally with the first electrode taking-out pad 7b (the negative electrodes 31b and 32b). Further, as shown in FIG. 4(c), the second bonding portion 50a is formed integrally with the second electrode taking-out pad 8b electrically connected with the first electrode taking-out pad 7b. The other configurations are the same as those in the above modification.

In the modification above, the lower member 41 and the upper member 42 are formed simultaneously with the lower electrode 31 and the upper electrode 32, respectively, but a predetermined interval is provided between the lower member 41 and the lower electrode 31 and between the upper member 42 and the upper electrode 32. In contrast, in the present modification, the negative electrodes 31b and 32b and the first bonding portion 40b are formed integrally with each other, and no interval is provided between the negative electrodes 31b and 32b, and the first bonding portion 40b. That is, as long as the positive electrodes 31a and 32a are insulated from the negative electrodes 31b and 32b, even when the first bonding portion 40b is connected to either the negative electrodes 31b and 32b or the positive electrodes 31a and 32a, an appropriate current can be supplied to the organic light emitting unit 3. Further, according to the present modification, an interval may not be provided between the first bonding portion 40b, and either the negative electrodes 31b and 32b or the positive electrodes 31a and 32a. Thus, by an area corresponding to that interval, the area of the region, in the organic EL substrate 4, for which the organic light emitting unit 3 is not formed can be reduced. Also with respect to the sealing cap substrate 5, an interval may not be provided between the second bonding portion 50a and the second electrode taking-out pad 8b, and thus, the size thereof can be reduced. Accordingly, without changing the size of the organic light emitting unit 3, the entirety of the element can be downsized.

It should be noted that the present invention is not limited to the above embodiment, and various modifications can be made. For example, in the embodiment described above, with respect to the organic EL substrate 4 and the sealing cap substrate 5, a configuration in which one pair of electrode taking-out pads respectively corresponding to a positive electrode and a negative electrode connected to the organic light emitting unit 3 are provided has been described. However, a plurality of pairs of electrode taking-out pads may be provided. Further, in the recess 61 of the sealing cap substrate 5, a light-reflecting layer may be formed. Accordingly, light emitted toward the sealing cap substrate 5 side from a portion, of the organic light emitting unit 3, for which the upper electrode 32 is not provided, can be reflected to the translucent substrate 2 side by means of the recess 61, to be taken out of the element. Further, a space between the recess 61 and the upper electrode 32 may be filled with a desiccant or the like.

### DESCRIPTION OF THE REFERENCE CHARACTERS

1 organic EL element
2 translucent substrate
3 organic light emitting unit
31 upper (SIC. correctly lower) electrode
31a positive electrode
31b negative electrode
32 lower (SIC. correctly upper) electrode
32a positive electrode
32b negative electrode
4 organic EL substrate
40 first bonding portion
40a first bonding portion
40b first bonding portion
5 sealing cap substrate
50 second bonding portion
50a second bonding portion
61 recess
62 through-hole
7a first electrode taking-out pad (positive electrode)
7b first electrode taking-out pad (negative electrode)
8a second electrode taking-out pad (positive electrode)
8b second electrode taking-out pad (negative electrode)
9a through-wiring (positive electrode)
9b through-wiring (negative electrode)

1. An organic EL element comprising: an organic EL substrate including an organic light emitting unit provided on one surface of a translucent substrate; and a sealing cap substrate which is provided on the organic EL substrate and which seals the organic light emitting unit,
the organic EL substrate including:
a lower electrode and an upper electrode which feed power to the organic light emitting unit;
a first electrode taking-out pad provided in these electrodes; and
a first bonding portion provided in a peripheral portion of the translucent substrate,
the sealing cap substrate including:
a recess provided at a position opposed to the organic light emitting unit;
a second electrode taking-out pad provided at a position opposed to the first electrode taking-out pad;
through-wiring provided so as to pass through the sealing cap substrate from the second electrode taking-out pad to an opposite side of the organic EL substrate; and
a second bonding portion provided at a position opposed to the first bonding portion, and
the first bonding portion and the second bonding portion being bonded together through surface activated bonding.

2. The organic EL element according to claim 1, wherein
a connection surface between the first electrode taking-out pad and the second electrode taking-out pad is flush with a bonding interface between the first bonding portion and the second bonding portion.

3. The organic EL element according to claim 1, wherein
as the first bonding portion, either one or both of the lower electrode and the upper electrode is(are) used.

4. The organic EL element according to claim 3, wherein
the first bonding portion is formed integrally with the first electrode taking-out pad, and
the second bonding portion is formed integrally with the second electrode taking-out pad.

5. A method for manufacturing an organic EL element, the method comprising:
a step of forming, on a translucent substrate, lower electrodes respectively corresponding to a positive electrode and a negative electrode which feed power to an organic light emitting unit;
a step of forming the organic light emitting unit so as to extend over the translucent substrate and a lower electrode;
a step of forming upper electrodes on the lower electrodes and on the organic light emitting unit, and of determining portions, of the upper electrodes, for which the organic light emitting unit is not provided, as first electrode taking-out pads;
a step of forming, in a peripheral portion of the translucent substrate, a first bonding portion so as to be flush with the upper electrodes;
a step of forming a recess at a position, in a sealing cap substrate sealing the organic light emitting unit, opposed to the organic light emitting unit;
a step of forming through-holes at positions, in the sealing cap substrate, opposed to the first electrode taking-out pads;
a step of forming through-wiring in the through-holes;
a step of forming a second bonding portion and second electrode taking-out pads at positions, in the sealing cap substrate, opposed to the first bonding portion and the first electrode taking-out pads, respectively; and
a step of bonding the first bonding portion and the second bonding portion together through surface activated bonding, in a state where the first electrode taking-out pads are respectively in contact with the second electrode taking-out pads.

6. The organic EL element according to claim 2, wherein
as the first bonding portion, either one or both of the lower electrode and the upper electrode is(are) used.
